(19) United States
(12) Patent Application Publication
(10) Pub. No.: US 2007/0212842 A1
(43) Pub. Date: Sep. 13, 2007

(54) Manufacturing method of high-voltage MOS transistor

(75) Inventor: Hisayuki Maekawa, Miyagi (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/588,220

(22) Filed: Oct. 27, 2006

(30) Foreign Application Priority Data
Mar. 13, 2006 (TW) 2006-067446

(51) Int. Cl. H01L 21/336

(52) U.S. Cl. 438/305

(57) ABSTRACT

In the manufacturing method of a high-voltage MOS, a structural body is prepared. The structural body includes a semiconductor substrate of a first conductivity type, a gate electrode formed on the semiconductor substrate via a gate insulation film, and first conductive layers of a second conductivity type extending from the surface to the inside of the semiconductor substrate. Main sidewalls are formed on the first conductive layers, and contact whole side surfaces of the gate electrode. Side surfaces of the main sidewalls are perpendicular to the surface of the semiconductor substrate. At least one sub-sidewall is formed on at lest one first conductive layer, and contacts a whole side surface of the main sidewall. Impurities are doped into exposed regions of the first conductive layer through the mask using the gate electrode, the main sidewalls and the sub-sidewall, to thereby form heavily-doped impurity regions of the second conductivity type.

### BACKGROUND OF THE INVENTION

This invention relates to a semiconductor device, and particularly relates to a manufacturing method of a high-voltage MOS transistor having a gate overlap LDD (Lightly-Doped Drain) structure.

There is known a MOS transistor having a gate overlap LDD structure that shows high current driving capability, as disclosed in, for example, Japanese Laid Open Patent Publication No. 5-218066.

FIG. 9 shows the conventional n-MOS transistor having the gate overlap LDD structure disclosed in the above described publication.

As shown in FIG. 9, the conventional n-MOS transistor having the gate overlap LDD structure includes a p-type silicon substrate 110 composed of p-silicon. An element separating oxide film 112 (i.e., an element separating region) and a gate oxide film 114 composed of a silicon oxide film having the thickness from 100 to 200 Å are formed on the main surface of the silicon substrate 110. A gate electrode 116 composed of polysilicon having the thickness from 3000 to 4000 A doped with n-type impurities is formed on the silicone substrate 110 via the gate oxide film 114. Lightly-doped n-type diffusion layers 120 and heavily-doped p-type diffusion layers 122 are formed extending from the main surface to the inside of the silicon substrate 110. Side walls 118 are formed on the side surfaces of the gate electrode 116, and are composed of the same type of polysilicon as the lightly-doped n-type diffusion layers 120.

In the MOS transistor disclosed in the above described publication, the sidewalls of polysilicon are provided to obtain the gate overlap LDD structure. In this structure, the sidewalls are conductive bodies, and therefore the electrical potentials of the sidewalls become the same as the electrical potential of the gate electrode when the MOS transistor operates.

In a general MOS transistor having LDD structure, the sidewalls have a function to form the heavily-doped diffusion layers (i.e., source and drain) on regions offset from the gate electrode in a self-alignment manner. The LDD structure has an effect of keeping the electric field generated in a depletion layer in the vicinity of the drain region (due to the voltage applied to respective electrodes when the transistor operates) as low as possible, and an effect of spreading the electric field to the drain region. As a result, the sidewalls contribute to prevention of the generation of substrate current due to impact ionization in the vicinity of the drain region and prevention of the degradation of hot carrier.

However, in the MOS transistor disclosed in the above described publication, the gate electrode (with the conductive sidewalls) is disposed adjacent to the heavily-doped diffusion layers constituting the source and drain regions, and therefore it is structurally difficult to restrict the generation of the electric field in the depletion layer in the vicinity of the drain region. Therefore, the above described MOS transistor can be used only at a low voltage that does not cause the high electric field. As a result, the above described MOS transistor can be used at a lower voltage and has substantially lower current driving capability, compared with the conventional MOS transistor having the LDD structure having insulating sidewalls and having no gate overlap.

As described above, in the MOS transistor disclosed in the above described publication, when high voltage is applied to the respective electrodes, high electric field may be generated in the depletion layer underneath the end of the gate electrode in the vicinity of the drain region. However, if it becomes possible to restrict the electric filed in the depletion layer, such MOS transistor can be used at a high voltage.

FIG. 10 is a graph showing the relationship between the offset length, i.e., the distance between the gate electrode and the drain region (i.e., the heavily-doped diffusion layer) and the withstand voltage of the MOS transistor of the gate overlap LDD structure. The vertical axis indicates the withstand voltage (V) of the transistor. The horizontal axis indicates the offset length (μm), i.e., the distance between the gate electrode and the drain region. As shown in FIG. 10, as the offset length increases, the withstand voltage increases, i.e., the electric field generated in the drain region (heavily-doped diffusion layer) is relieved. For example, in order to obtain the withstand voltage of approximately 15 V, the offset length of approximately 0.2 μm is needed. In order to obtain the withstand voltage of approximately 20 V, the offset length of 0.3 μm or more is needed.

However, the conventional MOS transistor having the LDD structure has a withstand voltage of approximately 10 V, and generally operates at 5 V or less. The manufacturing method of the MOS transistor having the gate overlap LDD structure which can operate at the voltage of approximately 15 V or more is not known.

### SUMMARY OF THE INVENTION

An object of the present invention is to provide a manufacturing method of a high-voltage MOS transistor which can operate at a high voltage.

The present invention provides a manufacturing method of a high-voltage MOS transistor. In the manufacturing method, a structural body is prepared. The structural body includes a semiconductor substrate of a first conductivity type, a gate electrode formed on a surface of the semiconductor substrate via a gate insulation film, and first conductive layers of a second conductivity type formed extending from the surface to the inside of the semiconductor substrate. The first conductive layers are disposed on both sides of the gate electrode symmetrically to each other as the semiconductor substrate is seen from the above described surface side.

Then, main sidewalls having electric conductivity are formed respectively on the first conductive layers so that the main sidewalls contact whole side surfaces of the gate electrode. Side surfaces of the main sidewalls opposite to the gate electrode are perpendicular to the surface of the semiconductor substrate.

Next, at least one sub-sidewall having insulation property is formed on at least one of the first conductive layers so that the sub-sidewall contacts a whole side surface of at least one of the main sidewalls opposite to the gate electrode.

Then, impurities of the second conductivity type are doped into regions of the first conductive layers via a mask constituted by the gate electrode, the main sidewalls and the sub-sidewall so as to form heavily-doped impurity regions of the second conductivity type in which the density of the impurities is higher than the first conductive layers.

With such a method, the high-voltage MOS transistor having the gate overlap LDD structure is manufactured.

In the above described manufacturing method, the side surfaces of the main sidewalls opposite to the gate electrode are perpendicular to the surface of the semiconductor substrate. Therefore, the sub-sidewall (for forming the heavily-doped impurity region on a region offset from the gate electrode) can be formed on the side surface of the main sidewall opposite to the gate electrode, using the characteristics that the sidewall can be formed only on the vertical side surface of the main sidewall. The offset length is determined by the width of the sub-sidewall in the direction of the gate length. Therefore, by forming the sub-sidewall having the width in accordance with a driving voltage, it becomes possible to restrict the electric field in the depletion region in the vicinity of the drain region (i.e., one of the heavily doped impurity regions of the second conductivity type on both sides of the gate electrode). Thus, the MOS transistor can be driven at high voltage.

### BRIEF DESCRIPTION OF THE DRAWINGS

In the attached drawings:

FIG. 1 is a sectional view illustrating a manufacturing method of a high-voltage MOS transistor according to the embodiment of the present invention;

FIG. 2 is a sectional view illustrating the manufacturing method of the high-voltage MOS transistor according to the embodiment of the present invention;

FIG. 3 is a sectional view illustrating the manufacturing method of the high-voltage MOS transistor according to the embodiment of the present invention;

FIG. 4 is a sectional view illustrating the manufacturing method of the high-voltage MOS transistor according to the embodiment of the present invention;

FIG. 5 is a sectional view illustrating the manufacturing method of the high-voltage MOS transistor according to the embodiment of the present invention;

FIG. 6 is a sectional view illustrating the manufacturing method of the high-voltage MOS transistor according to the embodiment of the present invention;

FIG. 7 is a sectional view illustrating the manufacturing method of the high-voltage MOS transistor according to the embodiment of the present invention;

FIG. 8 is a sectional view illustrating the manufacturing method of the high-voltage MOS transistor according to the embodiment of the present invention;

FIG. 9 is a sectional view illustrating the conventional n-type MOS transistor having gate overlap LLD structure; and

FIG. 10 is a graph showing the relationship between an offset length (a distance between a gate electrode and a heavily-doped diffusion layer constituting a drain region) and a withstand voltage of the transistor.

### DETAILED DESCRIPTION OF THE PREFERRED EMBODIMENT

An embodiment of the present invention will be described with reference to the attached drawings. The shape, size and positions of the respective components are schematically shown in the drawings only for the purpose of facilitating understanding of the present invention. The conditions or the like described hereinafter are merely an example within the scope of the present invention.

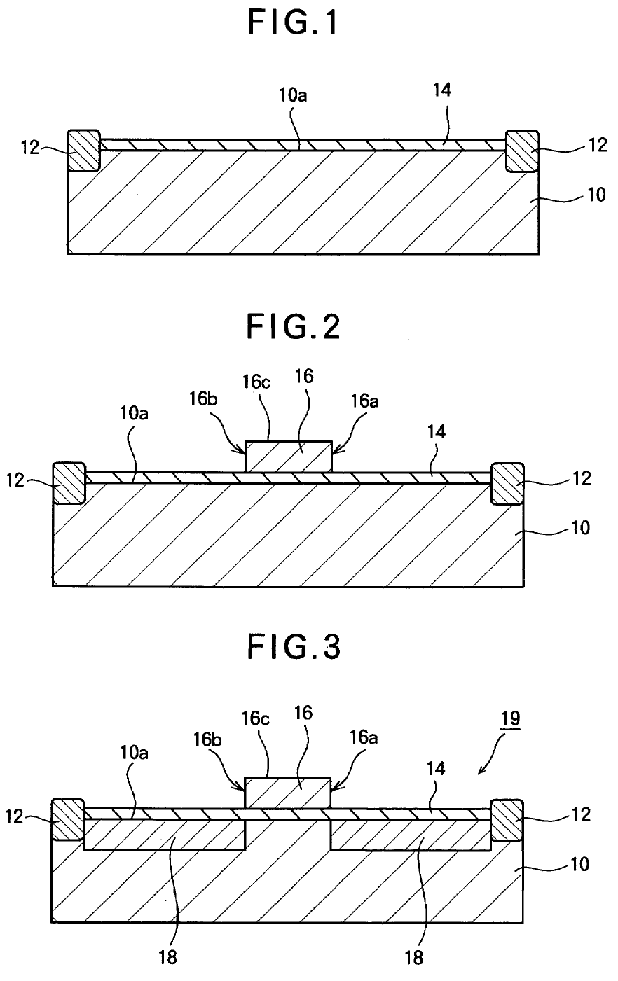

FIGS. 1 through 8 are sectional views illustrating a manufacturing method of a high-voltage MOS transistor according to the embodiment of the present invention. FIGS. 1 through 8 show cross sections of structural bodies obtained at respective steps of the manufacturing process. Hereinafter, description will be made to the manufacturing method of an n-channel MOS transistor. In the manufacturing method, a structural body 19 shown in FIG. 3 is prepared. As shown in FIG. 3, the structural body 19 includes a semiconductor substrate 10 of the first conductivity type (for example, p-type silicon substrate), a gate electrode 16, and two first conductive layers 18 formed in the semiconductor substrate 10 to respectively constitute a source region and a drain region.

In order to prepare the structural body 19 (FIG. 3), a p-type silicon substrate is used as the semiconductor substrate 10 of the first conductivity type. As shown in FIG. 1, an element separating oxide film 12 is formed on the semiconductor substrate 10, using a conventional LOCOS (Local Oxidation Silicon) oxidation technique. Then, a gate oxide film 14 (also referred to as a gate insulation film) is formed on a surface 10a of the semiconductor substrate 10 using a conventional oxidation technique, for example, an oxidation process of silicon in the high temperature atmosphere (from 900 to 1000° C.) or the like. The thickness of the gate oxide film 14 is, for example, 500 Å.

Then, a first polysilicon layer (not shown) doped to n-type is deposited on the upper side of the semiconductor substrate 10, i.e., on the whole surface of the gate oxide film 14, using a conventional CVD (Chemical Vapor Deposition) technique. The thickness of the first polysilicon layer is, for example, 3000 Å. Next, etching process is performed on the first polysilicon layer using a conventional photolithography technique and a conventional etching technique so that the gate electrode 16 is formed (i.e., remains unremoved) on the gate oxidation film 14 as shown in FIG. 2. Generally, the gate electrode 16 is in the form of a rectangular parallelepiped, and has a flat top surface 16c parallel to the surface 10a of the semiconductor substrate 10. Further, the gate electrode 16 has two side surfaces 16a and 16b opposing each other in the direction of the gate length, and the side surfaces 16a and 16b are perpendicular to the surface 10a of the semiconductor substrate 10.

Next, the first conductive layers 18 of the second conductivity type are formed extending from the surface 10a to the inside of the semiconductor substrate 10 by means of a conventional ion implantation technique using the gate electrode 16 and the element separating oxide film 12 as the mask. As a result, the structural body 19 shown in FIG. 3 is obtained. To be more specific, the first conductor layers 18 are formed of, for example, lightly-doped n-type diffusion layers in which phosphorus (P) of approximately 1.0×10¹³ cm⁻² is implanted. With this ion implanting, the first conductive layers 18 are formed on regions of the semiconductor substrate 10 on both sides of the gate electrode 16 in the direction of the gate length in such manner that the first conductive layers 18 are symmetrical to each other with respect to the gate electrode 16 as seen from above (i.e., as the semiconductor substrate 10 is seen from the surface 10a side).

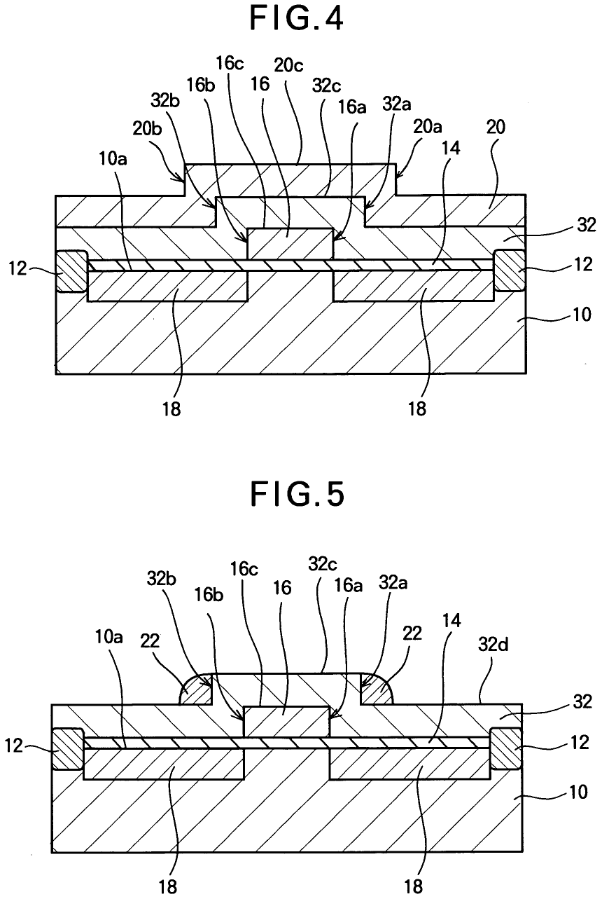

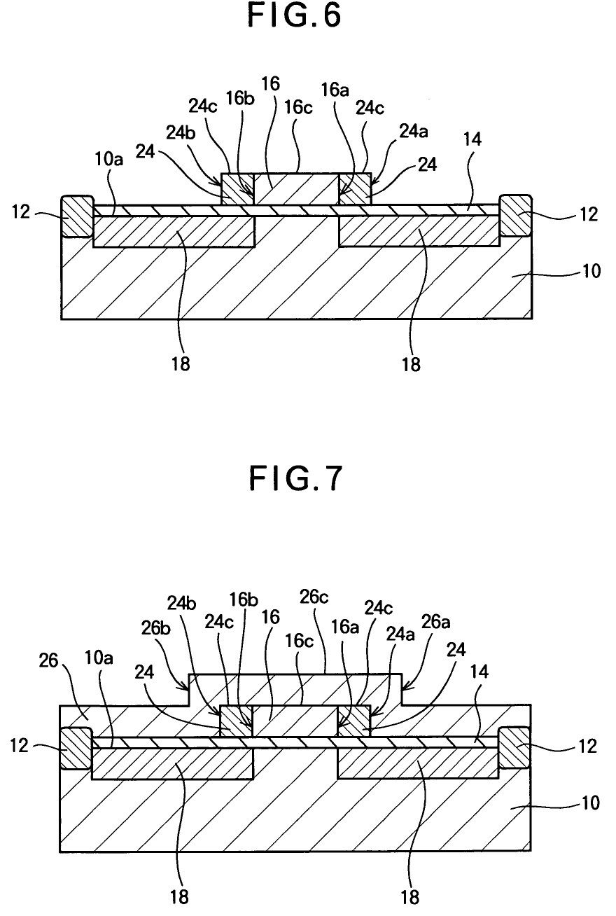

Then, main sidewalls 24 having electric conductivity are formed respectively on the first conductive layers 18 as shown in FIG. 6. In order to form the main sidewalls 24, a second polysilicon layer (i.e., a main-sidewall-forming film) 32 doped to n-type is deposited on the whole upper surface of the semiconductor substrate 10 including the gate electrode 16 to a uniform thickness of, for example, 2000 Å, using, for example, the conventional CVD technique. The second polysilicon layer 32 is formed into a convex shape having side surfaces 32a and 32b perpendicular to the surface 10a of the semiconductor substrate 10 and a top surface 32c parallel to the top surface 16c of the gate electrode 16. Next, as shown in FIG. 4, a first oxide film 20 (i.e., a first-sidewall-forming film) composed of, for example, silicon oxide film is deposited on the second polysilicon layer 32 to a uniform thickness of, for example, 1000 Å, using the conventional CVD technique. The first oxide film 20 is also formed into a convex shape having side surfaces 20a and 20b perpendicular to the surface 10a of the semiconductor substrate 10 and a top surface 20c parallel to the top surface 16c of the gate electrode 16.

Then, the first oxide film 20 is etched using a conventional etch-back technology until the surface of the second polysilicon layer 32 is exposed so that first sidewalls 22 are formed on both side surfaces 32a and 32b of the second polysilicon layer 32 as shown in FIG. 5. The first sidewalls 22 are formed as etching residue between the side surfaces 32a and 32b and an upper surface 32d of the second polysilicon layer 32 above the first conductive layers 18. The exposed surfaces of the first sidewalls 22 are outer convex surfaces formed between the top surface 32c and the upper surface 32d of the second polysilicon layer 32.

Next, the second polysilicon layer 32 is etched using the conventional etch-back technology. The etching selectivity ratio is so determined that the first sidewalls 22 are removed by etching when the etching of the second polysilicon layer 32 is completed. In other word, the etching selectivity ratio is determined based on the etching time for completing the etching of the second polysilicon layer 32 (i.e., for exposing the gate oxide film 14) and the etching time for removing the first sidewalls 22. With this etching process, second sidewalls 24 having side surfaces perpendicular to the surface 10a of the semiconductor substrate 10 are formed (i.e., remain unremoved by the etching) on the side surfaces 16a and 16b of the gate electrode 16, as shown in FIG. 6. The second sidewalls 24 have the same type of conductivity as the gate electrode 16. The second sidewalls 24 constitute the main sidewalls 24 having electric conductivity, and contact whole side surfaces 16a and 16b of the gate electrode 16. The main sidewalls 24 have side surfaces 24a and 24b perpendicular to the surface 10a of the semiconductor substrate 10 and the top surface 24c aligned on the same plane with the top surface 16c of the gate electrode 16.

As conventionally known, the etch-back technique is a method utilizing the anisotropy of the dry etching, in which a film (i.e., a to-be-etched film) formed on the whole surface of the wafer is etched without using a mask or the like so as to form sidewalls on side surfaces of the pattern underneath the to-be-etched film. In this regard, isotropic component is not zero even in the case of the dry etching, and therefore the to-be-etched film may also be etched in the lateral direction (i.e., from the side). In this embodiment, the first sidewalls 22 have a function to prevent parts of the second polysilicon layer 32 (i.e., parts to become the main sidewalls 24) from being excessively etched in the lateral direction (i.e., etched from the side). In other words, the first sidewalls 22 have a function to protect the side surfaces 24a and 24b of the main sidewalls 24 so that the side surfaces 24a and 24b are perpendicular to the surface 10a of the semiconductor substrate 10.

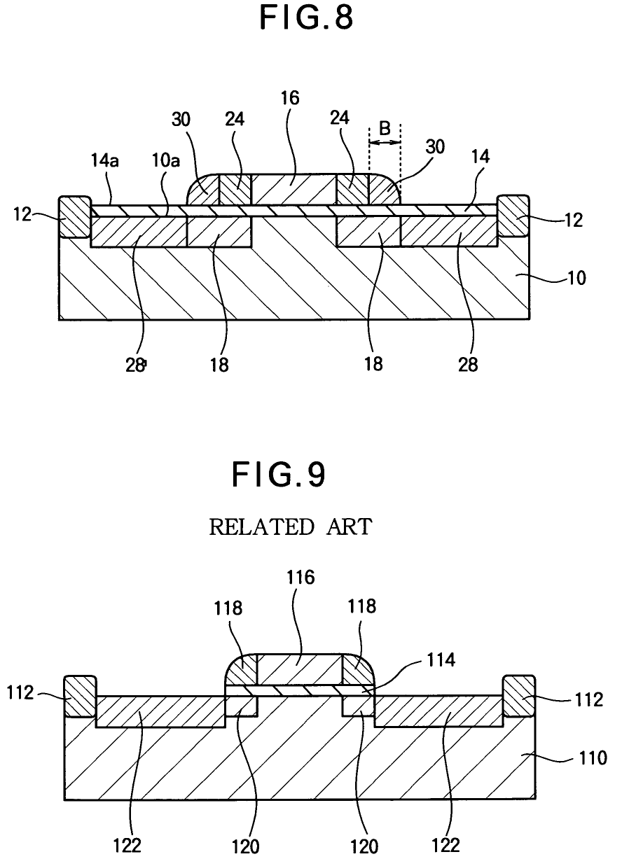

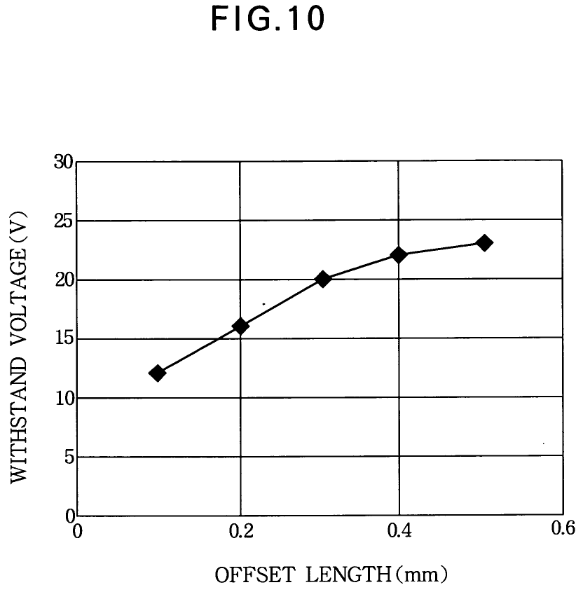

Next, sub-sidewalls 30 (FIG. 8) having insulation property are formed on the side surfaces 24a and 24b of the main sidewalls 24 above the first conductive layers 18. In order to form the sub-sidewalls 30, a second oxidation film (i.e., a sub-sidewall-forming film) 26 is formed on the whole upper surface of the semiconductor substrate 10 (on which the gate electrode 16 and the main sidewalls 24 are formed) to a uniform thickness of, for example, 4000 Å using the conventional CVD technique. As shown in FIG. 7, the second oxidation film 26 has a convex portion having side surfaces 26a and 26b (in the vicinity of the gate electrode 16) perpendicular to the surface 10a of the semiconductor substrate 10 and the top surface 26c parallel to the top surface 16c of the gate electrode 16.

Then, the second oxidation film 26 is etched using the conventional etch-back technique so that third sidewalls 30 are formed on the side surfaces 24a and 24b of the main (second) sidewalls 24, as shown in FIG. 8.

The third sidewalls 30 are formed as etching residue of the second oxidation film 26, and constitute the sub-sidewalls 30 having insulation property. The sub-sidewalls 30 are formed to sandwich the gate electrode 16 in the direction of the gate length of the gate electrode 16. The sub-sidewalls 30 are formed to contact the whole side surfaces 24a and 24b of the main sidewalls 24 opposite to the gate electrode 16, and are respectively disposed above the first conductive layers 18. The exposed surface of the sub-sidewalls 30 are outer convex surfaces formed between the top surfaces 24c of the main sidewalls 24 and a surface 14a of the gate oxidation film 14.

Next, for example, arsenide ion of approximately 5.0×15 cm⁻² is implanted into the first conductive layers 18 as the lightly-doped n-type diffusion layers, by means of the conventional photolithography technology and the ion implanting technology using the element separating oxide film 12, the gate electrode 16, the main sidewalls 24 and the sub-sidewalls 30 as the mask. As a result, heavily-doped impurity regions (i.e., heavily-doped n-type diffusion layers) 28 of the second conductivity type are formed. The heavily-doped impurity regions 28 have the higher density of the impurities than the first conductive layers 18. These two heavily-doped impurity regions 28 constitute the drain region and the source region.

With the above described method, the high-voltage MOS transistor is manufactured.

In the above description, the manufacturing method of the n-type MOS transistor is described. However, the manufacturing method can be applied to the p-type MOS transistor by changing the n-type and p-type to each other.

As described above, according to the manufacturing method of the embodiment of the present invention, the first sidewalls 22 (composed of the first oxide film) prevents the second polysilicon layer 32 from being etched in the lateral direction during the etching process of the second polysilicon layer 32. Therefore, it becomes possible to form the side surfaces 24a and 24b of the main (second) sidewalls 24 to be substantially perpendicular to the surface 10a of the semiconductor substrate 10. Since the side surfaces 24a and 24b of the main sidewalls 24 are vertical surfaces, the second oxide film 26 can be formed to contact the whole side surfaces 24a and 24b of the main sidewalls 24 so that the second oxide film 26 has a uniform thickness with respect to the surface 10a of the semiconductor substrate 10. As the sub-sidewalls 30 (i.e., the third sidewalls) have a function to form the heavily-doped impurity region 28 on a region offset from the gate electrode 16, it becomes possible to set the offset length sufficiently long, by forming the sub-sidewall 30 to have a sufficient width (for example, 0.4 μm) as indicated by “B” in FIG. 8.

Moreover, since the offset between the gate electrode 16 and the heavily-doped impurity region 28 can be obtained in a self-alignment manner (i.e., without using a mask), it becomes possible to restrict the variation of the offset length (i.e., the variation of the withstand voltage) due to the deviation of the overlaying of the masks that may occur if the heavily-doped impurity regions are formed by photolithography technique.

While the preferred embodiment of the present invention has been illustrated in detail, it should be apparent that modifications and improvements may be made to the invention without departing from the spirit and scope of the invention as described in the following claims. For example, various modification can be made to the structure, operation, number or the like of the above described preferred embodiment without departing from the spirit and scope of the invention.

In other words, the above described structure and operation are merely an example for facilitating understanding of the present invention, and does not limit the present invention. Thus, even if the structure, operation or the like is referred using the name which does not includes a part of (or all of) limitation, the structure, operation or the like is included in the present invention.

The preferred embodiment has been described with reference to the manufacturing method of the MOS transistor (IC chip) in which the source region and the drain region are disposed symmetrically to each other. However, the present invention can be applied to the MOS transistor (IC chip) in which the source region and the drain region are disposed asymmetrically to each other. In such a case, a process is added after the process shown in FIG. 5, in which the first sidewall 22 on the source side is removed using the conventional photolithography and etching technology, to thereby form one third sidewall (sub-sidewall) 30 only on the drain side.

What is claimed is:

1. A manufacturing method of a high-voltage MOS transistor comprising the steps of:
preparing a structural body including a semiconductor substrate of a first conductivity type, a gate electrode formed on a surface of said semiconductor substrate via a gate insulation film, and first conductive layers of a second conductivity type formed extending form said surface to inside of said semiconductor substrate, said first conductive layers being disposed on both sides of said gate electrode symmetrically to each other as said semiconductor substrate is seen from said surface side;
forming main sidewalls having electric conductivity respectively on said first conductive layers so that said main sidewalls contact whole side surfaces of said gate electrode, side surfaces of said main sidewalls opposite to said gate electrode being perpendicular to said surface of said semiconductor substrate;
forming at least one sub-sidewall having insulation property on at least one of said first conductive layers so that said sub-sidewall contacts a whole side surface of at least one of said main sidewalls opposite to said gate electrode;
doping impurities of the second conductivity type into exposed regions of said first conductive layers exposed through a mask using said gate electrode, said main sidewalls and said sub-sidewall so as to form heavily-doped impurity regions of said second conductivity type in which the density of said impurities is higher than said first conductive layers.

2. The manufacturing method according to claim 1, wherein said forming step of said main sidewalls includes the steps of:
forming a main-sidewall-forming film composed of a conductive material on said semiconductor substrate;
forming a first-sidewall-forming film on said main-sidewall-forming film;
etching said first-sidewall-forming film to thereby form first sidewalls on said side surfaces of said gate electrode; and
etching said main-sidewall-forming film and said first sidewalls to thereby form said main sidewalls on said side surfaces of said gate electrode.

3. The manufacturing method according to claim 2, wherein said main-sidewall-forming film is composed of polysilicon.

4. The manufacturing method according to claim 2, wherein said first-sidewall-forming film is formed of an oxide film.

5. The manufacturing method according to claim 2, wherein an etch-back technology is used in said etching step of said first-sidewall-forming film and in said etching step of said main-sidewall-forming film.

6. The manufacturing method according to claim 1, wherein said forming step of said sub-sidewall includes the steps of:
forming a sub-sidewall-forming film on said semiconductor substrate, said gate electrode and said main sidewalls; and
etching said sub-sidewall-forming film to thereby form said sub-sidewall on said side surface of said main sidewall.

7. The manufacturing method according to claim 6, wherein said sub-sidewall-forming film is formed of an oxide film.

8. The manufacturing method according to claim 6, wherein an etch-back technology is used in said etching step of said sub-sidewall-forming film.
